(19) United States
(12) Patent Application Publication
(10) Pub. No.: US 2011/0220892 A1
(43) Pub. Date: Sep. 15, 2011

(54) SEMICONDUCTOR DEVICE AND METHOD FOR MANUFACTURING THE SAME

(75) Inventor: Koichi Matsuda, Kawasaki-shi (JP)

(73) Assignee: CANON KABUSHIKI KAISHA, Tokyo (JP)

(21) Appl. No.: 13/046,564

(22) Filed: Mar. 11, 2011

(30) Foreign Application Priority Data
Mar. 15, 2010 (JP) 2010-057728
Feb. 15, 2011 (JP) 2011-029998

(51) Int. Cl. H01L 29/786; H01L 21/336

(52) U.S. Cl. 257/57; 438/151; 257/E29.273; 257/E21.411

(57) ABSTRACT

A semiconductor device has a substrate, a gate electrode, a insulating layer containing silicon nitride, a silicon layer containing crystalline silicon and amorphous silicon, a contact layer, and source and drain electrodes layered in this order. The volume content ratio of crystalline silicon in the silicon layer has a gradient increasing toward the source and drain electrodes and decreasing toward the substrate. The gate insulating layer and the silicon layer sandwich a silicon-oxide-containing layer therebetween.

### BACKGROUND OF THE INVENTION

1. Field of the Invention

The present invention relates to semiconductor devices (e.g., transistors) having a silicon active layer and particularly relates to a thin-film transistor having a crystalline-amorphous hybrid silicon film as its active layer and a method for manufacturing such a thin-film transistor.

2. Description of the Related Art

Thin-film transistors (TFTs) having a silicon active layer are used in circuits for driving the display panel of liquid crystal displays, organic electroluminescence (EL) displays, and other kinds of display apparatuses as a basic technology for such active-matrix display apparatuses. In many cases, TFTs have an amorphous silicon layer as its active layer; usually, however, the small carrier mobility of amorphous silicon necessitates that the amorphous silicon layer be fused by laser irradiation and recrystallized into a polycrystalline silicon film before being used in TFTs as the active layer.

Under well-controlled film formation conditions, however, microcrystalline silicon films can be formed by a film formation method similar to that for amorphous silicon films, with no laser annealing needed. Japanese Patent Laid-Open No. 8-097436 and 9-139503 propose that using plasma chemical vapour deposition (CVD) to form a microcrystalline silicon film and manufacturing TFTs with this film as the active layer. The latter publication also points out that the deposition of amorphous silicon was observed during the early stage of the formation of the microcrystalline silicon film. As can be seen from this, actually, microcrystalline silicon films are often hybrid films of coexisting amorphous and crystalline silicon regions despite their name.

As with amorphous silicon films, crystalline-amorphous hybrid silicon films are formed by plasma CVD or any other vapour deposition method. However, they can be directly used as a component of TFTs, with no process of fusing and recrystallization needed. Compared with low-temperature polysilicon films formed by rapid thermal annealing (RTA) or laser annealing, these hybrid silicon films can be formed to have a large area and manufactured at low cost because their manufacturing procedure needs no expensive equipment.

Furthermore, these hybrid silicon films have a greater carrier mobility than that of amorphous silicon films. The former is thus superior in characteristic to the latter in the use as a component of TFTs. Moreover, the hybrid silicon films are highly resistant to stress caused by electrical current and show only a small shift in threshold voltage (Vₜₕ) even after long-time operation.

For these advantages of theirs, the hybrid silicon films are expected to be used in a broad range of semiconductor devices in addition to TFTs.

When a freshly-formed silicon thin film is used as a component of a TFT with no further treatment, the carrier mobility highly depends on the condition of the joint between this silicon layer and the gate insulating layer. As mentioned above, crystalline-amorphous hybrid silicon films are directly used as a component of transistors, diodes, and other kinds of semiconductor devices, with no process of annealing needed. As a result, semiconductor devices having such a hybrid silicon film should meet the following requirement for better characteristics: The joint between the silicon layer and the gate insulating layer should be formed precisely enough for a reduced density of carriers trapped in the interface and an intended intensity of the gate electric field applied to the channel.

When formed on a substrate by CVD, however, a crystalline-amorphous hybrid silicon film easily detaches from the substrate. This is the case not only when it is formed on a glass substrate but also when it is formed on a silicon nitride film. For example, if such a hybrid silicon film is used as an active layer, bottom-gate transistors having a silicon nitride film as their gate insulating layer and other kinds of semiconductor devices having an equivalent structure will suffer from the detachment of the hybrid silicon film from the gate insulating layer, their performance will be poor, and their production yield will be low.

### SUMMARY OF THE INVENTION

The present invention provides a silicon semiconductor device. Making full use of the advantages of the crystalline-amorphous hybrid silicon film contained therein, this semiconductor device offers excellent electrical characteristics and is free from the detachment of the active layer from the gate insulating layer.

More specifically, the present invention provides a semiconductor device having a substrate, a gate electrode, a gate insulating layer containing silicon nitride, a silicon layer containing crystalline silicon and amorphous silicon, a contact layer, and source and drain electrodes layered in this order, the volume content ratio of crystalline silicon in the silicon layer increasing toward the source and drain electrodes and decreasing toward the substrate, wherein the gate insulating layer and the silicon layer sandwich a silicon-oxide-containing layer therebetween.

The present invention further provides a method for manufacturing a semiconductor device. This method includes the following steps of:

(A) forming a gate electrode and a gate insulating layer containing silicon nitride on a substrate in this order;

(B) forming a silicon-oxide-containing layer on the gate insulating layer;

(C) forming a silicon layer containing crystalline silicon and amorphous silicon by chemical vapour deposition (CVD) on the silicon-oxide-containing layer; and

(D) forming a contact layer and source and drain electrodes on the silicon layer in this order.

When a TFT has a crystalline-amorphous hybrid silicon film as its active layer and the crystalline silicon contained in this layer has a gradient in volume ratio increasing toward the source and drain electrodes and decreasing toward the substrate, this TFT may have a drawback: great stress on the hybrid silicon film that leads to easy detachment of the active layer. The present invention overcomes this drawback with the silicon-oxide-containing layer existing between the gate insulating layer and the hybrid silicon film. In other words, the present invention allows us to use crystalline-amorphous hybrid silicon films formed by CVD as a component of TFTs with no further treatment needed. Transistors obtained in this way have a great carrier mobility and good electrical characteristics, compared with TFTs produced using amorphous silicon. Furthermore, they can be manufactured easily because no laser annealing or any other kind of recrystallization is needed.

Further features of the present invention will become apparent from the following description of exemplary embodiments with reference to the attached drawings.

### BRIEF DESCRIPTION OF THE DRAWINGS

FIG. 1 illustrates a cross-section of a semiconductor device according to the present invention.

FIGS. 2A and 2B illustrate the formation of a crystalline-amorphous hybrid silicon layer by CVD in the early phase and late phase, respectively.

FIGS. 3A and 3B illustrate the formation of a crystalline-amorphous hybrid silicon layer by laser annealing in the early phase and late phase, respectively.

FIG. 4A to 4F illustrate a manufacturing procedure of a semiconductor device according to the present invention.

FIG. 5 is a chart of secondary ion mass spectroscopy (SIMS) of a semiconductor device of the present invention.

FIG. 6 is a cross-sectional transmission electron microscope (TEM) image obtained for the semiconductor device obtained in Example 2.

FIG. 7 is a cross-sectional TEM image obtained for the semiconductor device obtained in Comparative Example 2.

FIG. 8 shows the mobility of semiconductor devices produced with various dilution factors.

FIG. 9 shows the volume content ratio of crystalline silicon in semiconductor devices produced with various dilution factors.

### DESCRIPTION OF THE EMBODIMENTS

The following describes a preferred embodiment of the present invention with reference the drawings.

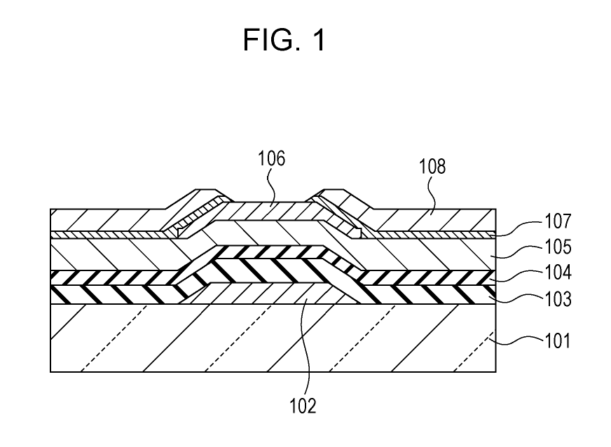

FIG. 1 illustrates a cross-section of the laminar structure of a bottom-gate TFT, a semiconductor device according to this embodiment.

As can be seen from the drawing, a glass substrate 101 has a gate electrode 102 formed thereon, and the glass substrate 101 and the gate electrode 102 are covered with a gate insulating layer 103. The gate electrode 102 is a metal electrode having a pattern. The gate insulating layer 103 is a silicon nitride film.

Mediated by the gate insulating layer 103, the gate electrode 102 is covered with a silicon-oxide-containing layer 104 and a crystalline-amorphous hybrid silicon layer 105 (hereinafter, simply referred to as a silicon layer 105). The silicon layer 105 has an etching stopper layer 106 formed in the channel portion. The silicon layer 105 and the etching stopper layer 106 are covered with a contact layer 107 and source and drain electrodes 108. The contact layer 107 is made of an impurity-doped semiconductor, and the source and drain electrodes 108 are made of metal.

The silicon layer 105 contains both crystalline and amorphous silicon regions. As will be detailed later, the proportion in volume of the former to the latter (hereinafter, simply referred to as the crystalline-to-amorphous proportion) varies along the thickness direction.

This silicon layer 105 is formed by plasma CVD. In the present invention, plasma CVD represents a film formation method including the following procedure: introducing a raw material gas containing silicon atoms into a reaction vessel and then applying high-frequency electric power to the system to decompose the raw material gas with plasma so that the silicon atoms can be deposited on a substrate to form a solid film. The structure of the resultant silicon layer varies depending on the concentration of the raw material gas and other film formation conditions. CVD allows various sets of film formation conditions, thereby making it possible to form films with different crystalline-to-amorphous proportions, ranging from pure amorphous silicon films to ones rich in crystalline silicon.

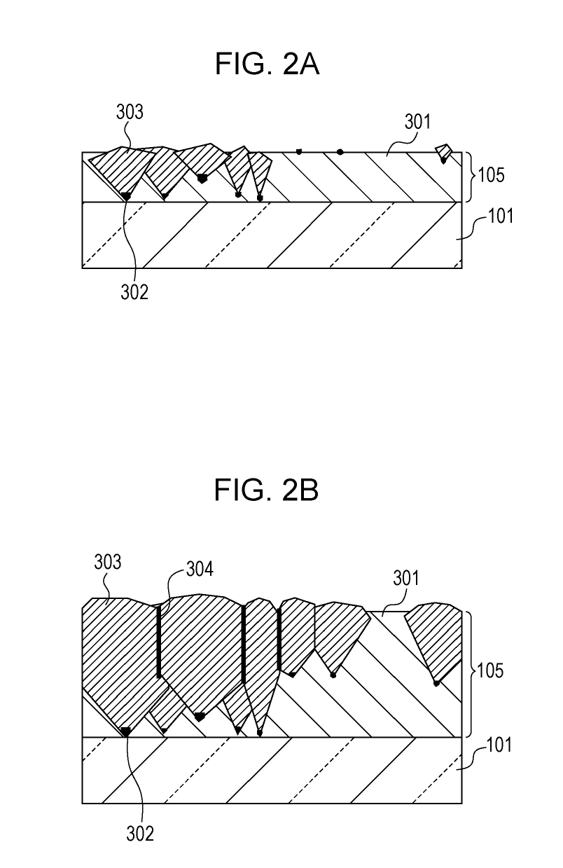

When CVD is used to form a silicon film on a glass substrate or a silicon nitride or silicon oxide film formed on a substrate, the volume content ratio of crystalline silicon in the resultant silicon film has a gradient increasing toward the exposed surface and decreasing toward the substrate even if the gas concentration and other film formation conditions are fixed. This proportion gradient along the thickness direction is attributable to the way of growing of the silicon layer during the plasma CVD process. The following explains this phenomenon with reference to FIGS. 2A and 2B.

FIG. 2A illustrates a cross-section of a silicon layer 105 in the early stage of its growth. During the initial stage of the film formation process, the silicon layer 105 is mainly composed of amorphous silicon 301. As the film formation process proceeds, however, fine silicon seed crystals 302 come to appear in amorphous silicon 301. The generation probability of the seed crystals 302 can be controlled by adjusting film formation conditions. Under a condition for forming films rich in crystalline silicon, this probability is high, and the seed crystals 302 are generated in the early stage of film formation. Under a condition for forming films poor in crystalline silicon, however, this probability is low, and the seed crystals 302 are hardly generated.

Once a seed crystal 302 is generated, crystalline silicon 303 grows around it. Starting from a seed crystal 302, crystalline silicon 303 develops upward along the thickness direction. The volume content ratio of crystalline silicon 303 measured at a certain height from the substrate 101 gets larger as the height increases. The seed crystals 302 can be generated not only when the silicon layer 105 has a particular thickness; they are generated with a certain probability on a surface of amorphous silicon 301 at any thickness. This means that the formation of the seed crystals 302 and the growth of crystal silicon 303 proceed together during the middle stage of the film formation process. Crystalline silicon 303 grows even around the seed crystals 302 formed during this stage, thereby further increasing its volume content ratio in the silicon layer 105. Under a condition for forming films poor in crystalline silicon, however, the growth of crystalline silicon 303 is slow for the progress of the film formation process.

FIG. 2B illustrates the same cross-section of the silicon layer 105 in the later stage of its growth. After growing to a certain size, grains of crystal silicon 303 come into contact with the neighboring ones, stop growing in the planar direction, and form crystal grain boundaries 304 therebetween. Even after the crystal grain boundaries 304 are formed, however, the grains of crystal silicon 303 still grow upward in the thickness direction.

In this way, the silicon layer 105 comes to contain three regions: The one the closest to the substrate 101 is mainly composed of amorphous silicon 301; another one, extending in the middle of the silicon layer 105, is a mixture of amorphous silicon 301 with crystalline silicon 303 that has grown around the seed crystals 302, and yet another one, the farthest away from the substrate 101, is mainly composed of crystalline silicon 303. When measured at a certain height from the surface of the substrate 101, the crystalline-to-amorphous proportion is 0:100 at the zero height (the bottom of the silicon layer 105); however, the volume content ratio of crystalline silicon 303 gets higher as the height increases, finally reaching 100% at the maximum height (the exposed surface of the silicon layer 105). If the film formation process is prematurely terminated, amorphous silicon 301 is exposed through some portions of the surface of the silicon layer 105 as illustrated in FIG. 2B. The higher the volume content ratio of crystalline silicon 303, the better; thus, the film formation conditions should be so chosen that the generation probability of the seed crystals 302 be as high as possible. Under usual film formation conditions, accordingly, each grain of crystalline silicon 303 has a size equal to or smaller than 100 nm.

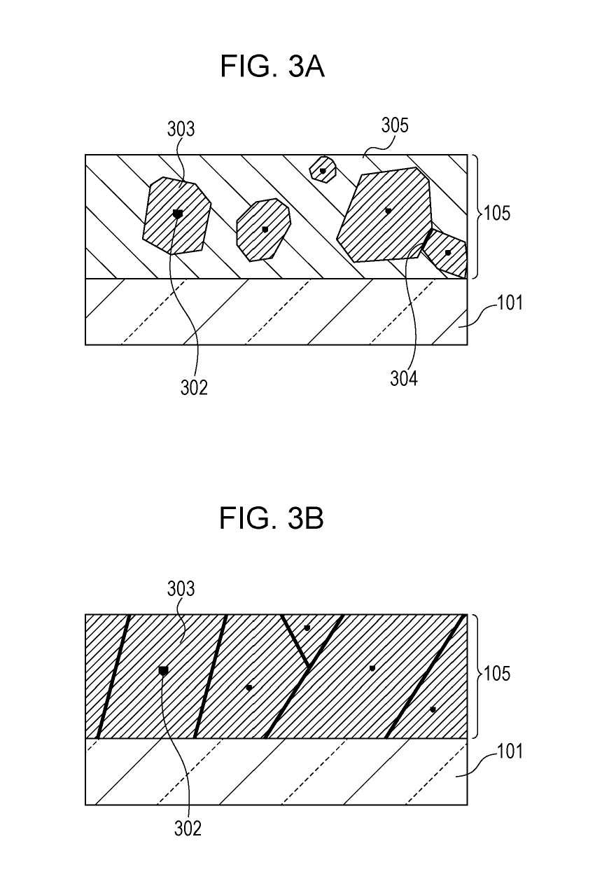

FIGS. 3A and 3B illustrate a cross-section of a silicon layer obtained by forming an amorphous silicon layer and then recrystallizing it by laser annealing. FIG. 3A is for the silicon layer being recrystallized, whereas FIG. 3B is for that after the completion of recrystallization.

The silicon layer 105 is fused by laser irradiation and then allowed to cool. While the silicon layer 105 is cooling down, seed crystals 302 are generated in fused silicon 305 as illustrated in FIG. 3A. Although one can make the seed crystals 302 selectively in particular positions in fused silicon 305, they are usually generated in random positions. Once a seed crystal 302 is generated, crystalline silicon 303 grows around it nearly isotropically; in other words, crystalline silicon 303 develops in all directions to a similar extent.

Then, grains of crystalline silicon 303 come into contact with the neighboring ones and form crystal grain boundaries 304; however, these crystal grain boundaries 304 are not necessarily perpendicular to the substrate 101.

As a result, the finished silicon layer 105 contains grains of crystalline silicon 303 of random sizes in random positions therein, and these grains are in contact with each other with the crystal grain boundaries 304 mediating therebetween, as illustrated in FIG. 3B. In some cases, some portions of fused silicon 305 solidify with no seed crystals 302 generated therein, and amorphous silicon is left in these portions (not illustrated in the drawings).

In the silicon layer 105 illustrated in FIG. 3B, which is formed by laser annealing, crystal grains are larger than those in the silicon layer 105 illustrated in FIG. 2B, which is formed by CVD. Under usual conditions, the size of these crystal grains is equal to or larger than 300 nm. When the thickness of the silicon layer 105 is on the order of 50 nm, the size of the crystal grains is considerably larger than it. Therefore, the silicon layer 105 formed in this way can be regarded as a sheet of silicon crystals each occupying the entire thickness of the sheet.

Incidentally, silicon formed into a thin film is affected by internal stress. A possible reason for the generation of this internal stress is collisions of crystal grains on their growth front.

According to Yamaguchi Daigaku Kogakubu Kenkyu-Hokoku (the journal of Faculty of Engineering, Yamaguchi University) Vol. 53 No. 1 (2002), Crystal Growth Mode of Poly-Si Prepared by ELA —Relationship between the Grain Morphology and Hydrogens—, a collision of two crystal grains growing in different crystal plane directions induces stress in the boundary because of the contact of two growth fronts with different lattice constants. This stress works as tensile force on both sides of the crystal grain boundary.

In a silicon layer formed by CVD, as illustrated in FIGS. 2A and 2B, regions distant from the substrate contain more crystal grains coming into contact with each other and thus contain more crystal grain boundaries than the regions closer to the substrate. These crystal grain boundaries are generally perpendicular to the surface of the silicon layer, and thus, in this region, strong tensile force works in the planar direction. On the other hand, regions close to the substrate contain less crystal grains coming into contact with each other and thus are affected by weaker tensile force in the planar direction. The resultant gradient in tensile force along the thickness direction leads to a deformation of the silicon layer and, if the adhesive force of the silicon layer with the substrate is weak, causes the silicon layer to detach from the substrate.

Amorphous silicon is structurally flexible than crystalline silicon; the former can be more easily deformed by stress than the latter. With any gradient in the crystalline-to-amorphous proportion along the thickness direction, the silicon layer is deformed to a larger extent in regions richer in amorphous silicon than in those poorer in amorphous silicon and eventually detaches from the substrate even if the stress is constant along the thickness direction.

Put more simply, crystalline-amorphous hybrid silicon films having a gradient in the proportion of the two components along the thickness direction are often deformed by stress and detach from a substrate.

On the other hand, in a silicon layer formed by laser annealing or any other method that includes fusing and recrystallization processes, crystal grains are uniform in the thickness direction as illustrated in FIG. 3B; the crystalline-to-amorphous proportion has no gradient along the thickness direction. Furthermore, the density of crystal grain boundaries is small. As a result, the internal stress is weaker than in a silicon layer formed by CVD. This is probably the reason why crystalline-amorphous hybrid silicon layers formed by CVD are likely to detach from a substrate.

Bottom-gate transistors have a gate electrode 102, a gate insulating layer 103 (a silicon nitride film), and a silicon layer 105 (a silicon film) layered in this order. The silicon nitride film often detaches from the silicon film, and this may cause a gate voltage to be low for the level of voltage applied. Worse yet, cleaved bonds of silicon atoms on the interface trap carriers, thereby reducing the on-state current.

However, TFTs according to this embodiment have, as illustrated in FIG. 1, a silicon-oxide-containing layer 104. This silicon-oxide-containing layer 104 is sandwiched between a gate insulating layer 103 (a silicon nitride film) and a silicon layer 105 and prevents the gate insulating layer 103 from detaching from the silicon layer 105.

The reason why the insertion of this silicon-oxide-containing layer 104 prevents the detachment is yet to be ascertained. However, it can probably be explained as follows.

Oxygen atoms are more likely to be taken into silicon films than nitrogen atoms. In a laminate consisting of a gate insulating layer 103 (a silicon nitride film), a silicon layer 105, and a silicon-oxide-containing layer 104 formed between them, therefore, oxygen atoms move out from the silicon-oxide-containing layer 104 into the silicon layer 105. In amorphous silicon, bonds have different strengths, and weak ones are easily cleaved when a deforming force is applied. In silicon films, Si—N bonds are cleaved more easily than Si—Si bonds. Furthermore, the binding energy of Si—O bonds is higher than that of Si—N bonds (812 kJ/mol vs. 320 kJ/mol). As a result, the oxygen atoms taken into the silicon layer 105 bind with silicon atoms preexisting in it, making the silicon layer 105 stronger than in the case where nitrogen atoms bind with the silicon atoms. This probably contributes to the prevention of detachment. The silicon-oxide-containing layer 104 is formed by the oxidation of the gate insulating layer 103 (a silicon nitride film) on its surface or the deposition of silicon oxide on the gate insulating layer 103. The oxidation of the gate insulating layer 103 replaces nitrogen atoms on the surface with oxygen atoms, leaving a silicon nitride-oxide film or a hybrid film containing silicon nitride and silicon oxide. In the present invention, this kind of film is also referred to as a silicon-oxide-containing layer. Stoichiometrically, silicon oxide may have a monoxide (SiO) or dioxide (SiO₂) form; however, it contains Si—O bonds whether in the monoxide or dioxide form, and the silicon-oxide-containing layer 104 can always improve the adhesion between the gate insulating layer 103 and the silicon layer 105.

An effective method for oxidizing the gate insulating layer 103 is exposing the gate insulating layer 103 to a stream of oxygen for 30 seconds or longer. As described later, too large a thickness of the silicon-oxide-containing layer 104 affects the characteristics of the resultant transistor. The exposure time should not be so long; it is preferably equal to or shorter than 3600 seconds.

The substrate temperature during this oxidation process is preferably in the range of room temperature to 400° C. and should be appropriately changed depending on the duration of the process.

On the other hand, deposition-based methods include an ordinary CVD method.

The silicon-oxide-containing layer 104 can be directly observed under a transmission electron microscope (TEM). As mentioned in the Examples section below, on a TEM image this layer appears between the gate insulating layer 103 and the silicon layer 105 as a white line, which represents an insulating material. Besides TEM, secondary ion mass spectroscopy (SIMS) can also be used to confirm the presence of oxygen.

Methods for forming the silicon layer 105 include one in which the deposition of silicon and the irradiation of the formed coating with hydrogen plasma are alternated, one in which this set of processes is repeated in the early stage and then switched to the serial formation of silicon coatings, and so forth. Although different methods may result in different gradients in the crystalline-to-amorphous proportion, any method may be used as long as it provides a gradient in the volume content ratio of amorphous silicon increasing toward the substrate and decreasing toward the opposite side.

In TFTs according to the present invention, the volume content ratio of crystalline silicon in the silicon layer 105 is at least 20% and preferably equal to or higher than 40%, averaged over the entire thickness of the silicon layer 105.

The volume content ratio of crystalline silicon in a silicon film can be measured by evaluating the silicon film by Raman spectroscopy for the degree of crystallinity. In this analytical method, the Raman shift for crystalline silicon and that for amorphous silicon are measured at 520 cm⁻¹ and 480 cm⁻¹, respectively, and then the intensity ratio of the former to the latter is converted into the volume content ratio of crystalline silicon. The obtained result is a volume content ratio of crystalline silicon averaged over the entire thickness of the silicon film. As for the distribution of crystalline silicon and amorphous silicon along the thickness direction, cross-sectional TEM provide brief observations.

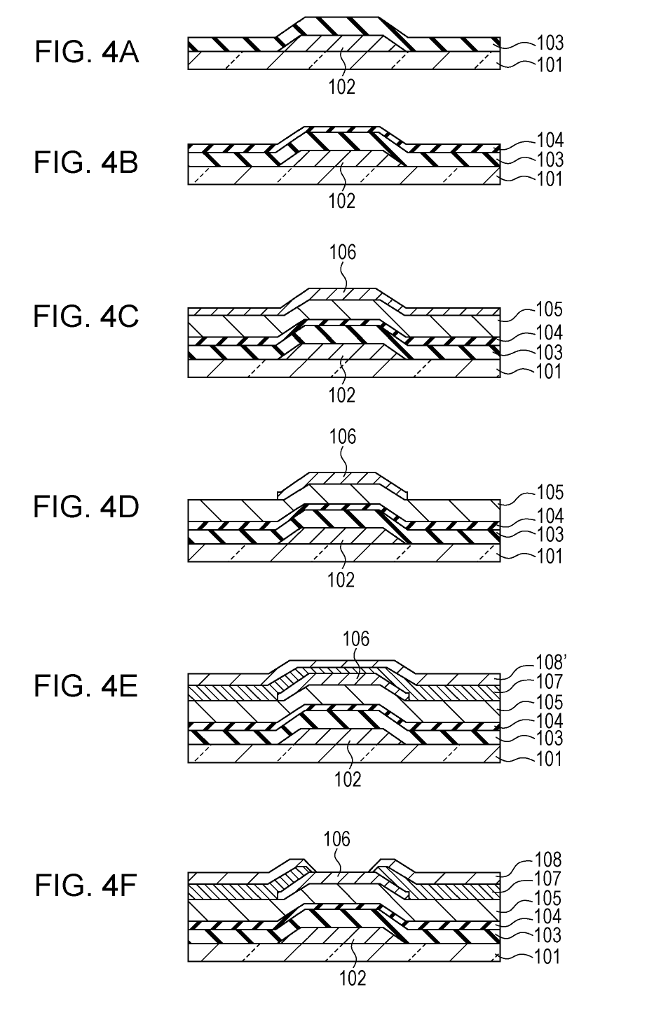

The following describes a method for manufacturing a TFT according to this embodiment, with reference to FIGS. 4A to 4F.

FIG. 4A illustrates a substrate 101 having a gate electrode 102 and a gate insulating layer 103. The gate electrode 102 is formed to have a thickness in the range of 10 to 300 nm, and the gate insulating layer 103 is then formed to cover the substrate 101 and the gate electrode 102. The gate electrode 102 has a pattern formed by photolithography to provide an intended electrode arrangement. The substrate 101 is made of high-melting glass, quartz, ceramics, or any other appropriate material. The material for the gate electrode 102 is molybdenum (Mo), titanium (Ti), tungsten (W), nickel (Ni), tantalum (Ta), copper (Cu), aluminum (Al), or an alloy of them, and this electrode is formed by sputtering, vacuum vapour deposition, or any other appropriate method. In addition, the gate electrode 102 may be formed by layering several metal coatings.

The gate insulating layer 103 is a silicon nitride film having a thickness in the range of 50 to 300 nm. This silicon nitride film is formed by the plasma CVD of a gas mixture containing silane (SiH₄), ammonia (NH₃), nitrogen (N₂), hydrogen (H₂), and so forth.

FIG. 4B illustrates the next process, in which the gate insulating layer 103 is processed to form a silicon-oxide-containing layer 104.

More specifically, the gate insulating layer 103 is treated by plasma CVD to have an oxide film deposited thereon, with a gas mixture containing SiH₄, nitrous oxide (N₂O), and oxygen (O₂) as the raw material gas. The raw material gas may be a combination of tetraethoxisilane (TEOS) and O₂ gases. In addition, CVD is not the only way of processing the gate insulating layer 103; it can be processed by exposing the structure covered with this layer to a water vapour atmosphere, an O₂ atmosphere, or an O₂⁻ containing mixed atmosphere at a high temperature. In this approach, for more rapid processing, plasma may be generated with a high-frequency wave or a direct-current (DC) electric field while the structure is being exposed to any of the atmospheres listed above.

This oxidation process leaves a silicon-oxide-containing layer 104 on the gate insulating layer 103. The thickness of the silicon-oxide-containing layer 104 is preferably equal to or smaller than 20 nm. Too large a thickness makes this layer a portion of the gate insulating layer 103, and the resultant TFT is difficult to turn off owing to its low on-to-off ratio (switching current ratio), as with TFTs the gate insulating layer of which is entirely made of silicon oxide. In fact, TFTs produced with the thickness of the silicon-oxide-containing layer 104 set at 10 nm or 5 nm had an on-to-off ratio of not less than 10⁵. On the other hand, TFTs produced with the thickness of the silicon-oxide-containing layer 104 set at greater than 20 nm had an on-to-off ratio on the order of 10².

In the present invention, the silicon-oxide-containing layer 104 is thinner than the gate insulating layer 103 by a factor of ten or more. Thus, the silicon-oxide-containing layer 104 does not behave as a gate insulating layer and has no influence on the threshold voltage, withstand voltage, and other characteristics of the resultant TFT; it serves only as a film that modifies the interface with a silicon layer 105 in the channel portion as mentioned above. The thickness of the silicon-oxide-containing layer 104 can be measured by TEM, secondary ion mass spectrometry, or any other known method.

Then, the silicon-oxide-containing layer 104 is covered with a silicon layer 105. This silicon layer 105 is formed by plasma CVD and contains crystalline silicon and amorphous silicon. The thickness of the silicon layer 105 is in the range of 20 to 200 nm and preferably in the range of 40 to 100 nm.

As for the conditions of CVD to form this silicon layer 105, the radiofrequency (RF) power density is in the range of 0.05 to 1 W/cm² and preferably in the range of 0.1 to 0.8 W/cm², and the reaction pressure is in the range of 1.0 to 10 Torr and preferably in the range of 1.5 to 8.0 Torr. The raw material gas is a gas mixture containing SiH₄, disilane (Si₂H₆), dichlorosilane (SiH₂Cl₂), tetrafluorosilane (SiF₄), and difluorosilane (SiH₂F₂), and the diluent gas is a H₂ gas or an inert gas. When a H₂ gas is used, the dilution factor for the silicon-based raw material gas is set within the range of 100 to 3000.

The dilution factor is defined by a ratio of amounts of the diluent gas to the raw material gas. In the present chemical vapour deposition process, it can be replaced by a ratio of the flow rate in the CVD chamber, i.e.,

Dilution factor=(flow rate of the diluent gas)/(flow rate of the raw material gas).

A high dilution factor of 1000 to 3000 is preferable for growth of a silicon layer on a silicon-oxide-containing layer. The preferred dilution factor varies depending on whether the silicon-based raw material gas contains halogen or not. A high dilution factor is preferred for raw material gases not containing halogen.

As can be seen from this, the conditions for forming the silicon layer 105 include a relatively high gas pressure and a relatively high factor of dilution in hydrogen, compared with those for forming amorphous-silicon films.

For better electrical characteristics of the silicon layer 105, it is effective to increase the volume content ratio of crystalline silicon in this silicon film. One of the ways to do this is to form this layer by alternating the deposition of silicon and the irradiation of the formed coating with hydrogen plasma. This can be achieved by appropriately setting the mass flow controllers for the gases involved. The time proportion between silicon deposition and hydrogen plasma irradiation should be appropriately controlled for the intended deposition speed and degree of crystallization.

FIG. 4C illustrates the next process, in which an etching stopper layer 106 is formed on the silicon layer 105. This etching stopper layer 106 is a monolayer of silicon oxide (SiOₓ), silicon nitride (SiNₓ), or silicon nitride-oxide (SiON) or a laminate formed as an appropriate combination of monolayers of these compounds.

FIG. 4D illustrates the next process, in which the etching stopper layer 106 is partially removed so that only the portion including the channel portion should be left with predetermined dimensions.

Although not illustrated in FIG. 4D, the silicon layer 105 may be isolated after this process to have an island pattern. One of the ways to do this is to mask the silicon layer 105 with a resist pattern and then remove the exposed portion by dry etching, wet etching, or both.

FIG. 4E illustrates the next process, in which the silicon layer 105 and the etching stop layer 106 are covered with a contact layer 107 and then with a metal layer 108′. The contact layer 107 contains an n-type dopant at a high density, and the metal layer 108′ serves as a material for the source and drain electrodes 108 formed later. To provide ohmic contact between the silicon layer 105 and the source and drain electrodes 108, the contact layer 107 has a thickness in the range of 10 to 300 nm and preferably in the range of 20 to 100 nm. The metal layer 108′, a material for the source and drain electrodes 108, is a monolayer of Mo, Ti, W, Ni, Ta, Cu, Al, or an alloy of them or a laminate formed as an appropriate combination of monolayers of these materials.

Then, the metal layer 108′ is masked with a photolithographically formed resist pattern. The exposed portion of the metal layer 108′ and the portion of the contact layer 107 existing therebeneath are removed by etching; during this process, the channel portion of the etching stopper layer 106 is made exposed, and the source and drain electrodes 108 are formed. If the silicon layer 105 is not isolated after the process illustrated in FIG. 4D, this etching process is continued until the appropriate portion of this silicon film is removed. In this way, a TFT patterned with the source and drain electrodes 108 is finished as illustrated in FIG. 4F.

Manufacturing procedures of transistors that do not have the etching stopper layer 106 exclude the processes illustrated in FIGS. 4C and 4D. Instead, in the process illustrated in FIG. 4F, the metal layer 108′ is patterned with the channel portion masked, and then the channel portion of the metal layer 108′ and the portion of the contact layer 107 existing therebeneath are removed.

Transistors manufactured using any of the procedures described above can be converted into diodes by short-circuiting the connection between the gate and the source electrode or that between the gate and the drain electrode. Other kinds of semiconductor devices can also be made in similar ways as long as their channel is controlled by gate voltage.

### EXAMPLES

The following describes the present invention with reference to examples.

### Example 1

First, a gate electrode 102 was formed on a glass substrate 101. More specifically, Mo was deposited on the glass substrate 101 by RF sputtering to a thickness of 100 nm. Then, the gate electrode 102 was patterned. The obtained samples were placed in a CVD chamber, and a gate insulating layer 103 was formed by deposition in accordance with Gate Insulating Layer Formation Conditions 1 (Table 1) to a thickness of 300 nm (FIG. 4A).

Subsequently, the samples were exposed to an O₂ atmosphere to oxidize the surface of the gate insulating layer 103 in accordance with Oxidation Conditions 1 (Table 2). The exposure time to the oxygen gas atmosphere was varied from 10 seconds to 3600 seconds as specified in Table 2. Samples of various exposure time were obtained and evaluated.

By this exposure to an oxygen gas atmosphere, a silicon-oxide-containing layer 104 (FIG. 4B) was formed.

Subsequently, the samples were placed back in the CVD chamber to form a silicon layer 105. This crystalline-amorphous hybrid silicon film was formed in accordance with Silicon Layer Formation Conditions 1 (Table 3).

Here, the dilution factor was 300 as determined by a ratio of the flow rate of hydrogen gas, 3000 sccm, to the flow rate of silane gas, 10 sccm.

Then, an etching stopper layer 106 was formed on the silicon layer 105 (FIG. 4C). This etching stopper layer 106 was a laminate of silicon nitride and silicon oxide films.

Subsequently, the etching stopper layer 106 was patterned by photolithography and wet etching so that some portion of the silicon layer 105 should be exposed (FIG. 4D). The etchant used here was hydrofluoric acid buffered with ammonium fluoride.

Then, a contact layer 107 was formed by plasma CVD, and source and drain electrodes 108 were formed by RF magnetron sputtering (FIG. 4E). The contact layer 107 and the source and drain electrodes 108 were then shaped together into a predefined pattern by dry etching (FIG. 4F).

TABLE 1
Gate Insulating Layer Formation Conditions 1

| Substrate temperature | 300° C. | |
|---|---|---|
| RF power | 0.10 | W/cm² |
| Pressure | 1.0 | Torr |
| Target thickness | 300 | nm |
| SiH₄ flow rate | 500 | sccm |
| NH₃ flow rate | 1000 | sccm |
| N₂ flow rate | 3000 | sccm |

TABLE 2
Oxidation Conditions1

| Temperature | 300° C. | |
|---|---|---|
| Pressure | 10 | Torr |
| O₂ flow rate | 100 | sccm |

| | |
|---|---|
| Exposure time | 10 to 3600 sec |

TABLE 3
Silicon Layer Formation Conditions 1

| Substrate temperature | 250° C. | |
|---|---|---|
| RF power | 0.20 | W/cm² |
| Pressure | 5.0 | Torr |
| Target thickness | 50 | nm |
| SiH₄ flow rate | 10 | sccm |
| H₂ flow rate | 3000 | sccm |

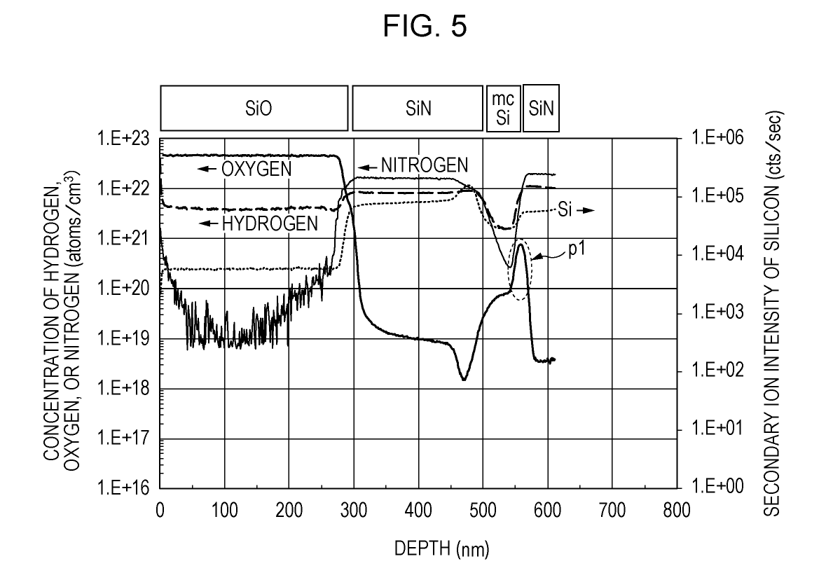

The TFT prepared in this way was analyzed by TEM over approximately 1 μm along the width direction for its laminar structure and the gradient in the crystalline-to-amorphous proportion in the silicon layer 105. More specifically, the target site was observed under a JEM-series transmission electron microscope available from JEOL Ltd. with a magnification of ×1,500,000. The thickness of the silicon-oxide-containing layer 104 was measured on the obtained image, and the distribution of crystalline silicon in the silicon layer 105 was determined from the arrangement of lattice fringes. On TEM images, in general, crystalline silicon regions are represented by lattice fringes, while amorphous silicon regions have no such fringes. The finished sample the gate insulating layer 103 of which was exposed to the oxygen gas atmosphere for 30 seconds was analyzed by SIMS using PHI ADEPT-1010 (ULVAC-PHI Inc.). FIG. 5 illustrates a result. In this drawing, the horizontal axis represents the depth from the surface, the left vertical axis the concentration of hydrogen, oxygen, or nitrogen based on the number of atoms, and the right vertical axis the secondary ion intensity of silicon. Sites not covered with the metal layer 108′ were chosen for measurement.

The depth ranges of 0 to approximately 300 nm (labeled “SiO” outside the plot area) and approximately 300 to 500 nm (labeled “SiN”) represent the etching stopper layer 106. The depth range of 500 to 560 nm (labeled “mcSi”; mc: microcrystalline) represents the silicon layer 105. The gate insulating layer 103 is situated in the level deeper than 560 nm (labeled “SiN”).

The interface between the silicon layer 105 (mcSi) and the gate insulating layer 103 (SiN) exists at around a depth of 560 nm. The concentration of oxygen based on the number of atoms has a peak (p1) near this interface. This peak corresponds to the silicon-oxide-containing layer 104. The peak concentration of oxygen based on the number of atoms is 8×10²⁰ atoms/cm³; it is two orders of magnitude greater than the oxygen concentration in the gate insulating layer 103 (SiN) and about an order of magnitude greater than that in the silicon layer 105 (mcSi).

In FIG. 5, the peak p1, which is a peak of the concentration of oxygen based on the number of atoms and corresponds to the silicon-oxide-containing layer 104, has a slope over a depth width of approximately 30 nm. However, this slope is an apparent slope attributable to the nature of SIMS in which a sample is scraped during measurement. On a TEM image, the silicon-oxide-containing layer 104 has a thickness smaller than determined on a SIMS spectrum from the width of the peak corresponding to it; TEM observations allow for more precise determination of the thickness of this layer than is possible with SIMS measurements. The values of the thickness of the silicon-oxide-containing layer 104 provided in this specification are all based on observations by TEM.

Then, electrical characteristics were measured for the same TFT. The measurement apparatus used here was Agilent 4155C Semiconductor Parameter Analyzer, and the sample stage was maintained at 25° C. during measurement. With voltages of 0 V and 10 V applied to the source electrode and the drain electrode, respectively, and the drain current (I_{D}) was measured while the gate voltage (V_{G}) was being swept from −20 V to +20 V. I_{D} measured at V_{G} of 10 V was defined as the on-state current.

The gain of I_{D} per 1 V V_{G} was calculated from the square roots of I_{D} measurements, and then the carrier mobility was determined from the maximum slope observed within the V_{G} range from −20 V to +20 V.

### Comparative Example 1

A bottom-gate TFT was prepared in the same way as in Example 1 except for the omission of the oxidation process. For the obtained TFT, electrical characteristics were measured and the carrier mobility was determined in the same way as in Example 1.

Samples in Example 1 exposed to the oxygen gas atmosphere not less than 30 seconds showed 1.5-times higher on-state current and carrier mobility, which were superior in characteristic to those obtained in Comparative Example 1. This superiority is probably because of an improved adhesion of the silicon layer 105 in the device obtained in Example 1.

For the TFT the gate insulating layer 103 of which was exposed to the oxygen gas atmosphere for 30 seconds in Example 1, the results of TEM analysis were as follows Thickness of the silicon-oxide-containing layer 104: 10 nm; Volume content ratio of crystalline silicon in the silicon layer 105: approximately 10% on the boundary with the silicon-oxide-containing layer 104, and 70% on the opposite boundary, the boundary with the etching stopper layer 106 and the contact layer 107. In the silicon layer 105, 50% of crystalline silicon grains were in close contact with neighboring ones, with crystal grain boundaries put therebetween.

On the other hand, the silicon-oxide-containing layer 104 was not observed in the sample the gate insulating layer 103 of which was exposed to the oxygen atmosphere for 10 seconds.

### Example 2

A bottom-gate TFT was prepared using the same procedure as in Example 1. However, the gate insulating layer 103 was formed in accordance with Gate Insulating Formation Conditions 2 (Table 4), the silicon-oxide-containing layer 104 was formed by CVD in accordance with Oxidation Conditions 2 (Table 5), and the silicon layer 105 was formed in accordance with Silicon Layer Formation Conditions 2 (Table 6) featuring a gas pressure higher than in Example 1.

TABLE 4
Gate Insulating Layer Formation Conditions 2

| Substrate temperature | 350° C. | |
|---|---|---|
| RF power | 0.05 | W/cm² |
| Pressure | 1.3 | Torr |
| Target thickness | 200 | nm |
| SiH₄ flow rate | 100 | sccm |
| NH₃ flow rate | 1000 | sccm |
| N₂ flow rate | 3000 | sccm |

TABLE 5
Oxidation Conditions 2

| Temperature | 300° C. | |
|---|---|---|
| Pressure | 1 | Torr |
| RF power | 200 | W |
| TEOS flow rate | 200 | sccm |
| O₂ flow rate | 1000 | sccm |

TABLE 6
Silicon Layer Formation Conditions 2

| Substrate temperature | 300° C. | |
|---|---|---|
| RF power | 0.20 | W/cm² |
| Pressure | 10.0 | Torr |
| Target thickness | 50 | nm |
| SiH₄ flow rate | 10 | sccm |
| H₂ flow rate | 3000 | sccm |

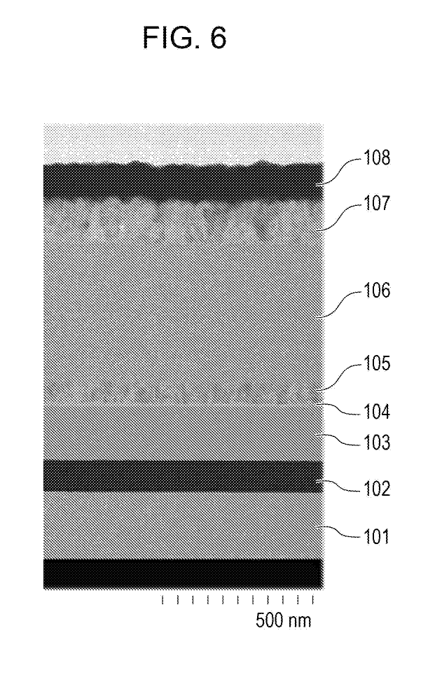

For the obtained TFT, electrical characteristics were measured and TEM analysis was carried out in the same way as in Example 1. FIG. 6 illustrates a TEM image obtained for this TFT. In FIG. 6, the numerals represent the components indicated by the same numerals in FIG. 1, and the scale provided at the bottom right has marks for every 50 nm. As can be seen in the image, a silicon-oxide-containing layer 104 (the white line) exists between a gate insulating layer 103 and a silicon layer 105.

### Comparative Example 2

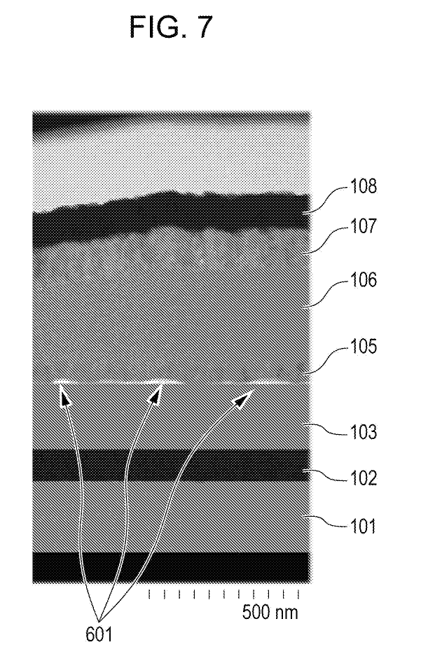

A bottom-gate TFT was prepared in the same way as in Example 2 except for the omission of the oxidation process. FIG. 7 illustrates a TEM image obtained for this TFT.

Samples in Example 2 showed a 1.2-times higher on-state current and a 1.3-times higher carrier mobility, which were superior in characteristic to those obtained in Comparative Example 2. For the TFT obtained in Example 2, the results of TEM analysis were as follows: Thickness of the silicon-oxide-containing layer 104: 15 nm; Volume content ratio of crystalline silicon in the silicon layer 105: approximately 10% on the boundary with the silicon-oxide-containing layer 104, and 60% on the opposite boundary. As mentioned above, Example 2 and Comparative Example 2 both featured a higher gas pressure for the formation of the silicon layer 105 than that used in Example 1; however, the values of the volume content ratio of crystalline silicon were not significantly different from those obtained in Example 1. As for the TFT obtained in Example 2, 70% of the crystalline silicon grains existing in the silicon layer 105 were in close contact with neighboring ones, with crystal grain boundaries put therebetween, demonstrating that the internal stress in the silicon layer 105 was greater in the device obtained in Example 2 than that obtained in Example 1.

As can be seen from FIG. 6, the TFT obtained in Example 2 was free from the detachment of the silicon layer 105 despite the greater internal stress in this film. On the other hand, the TFT obtained in Comparative Example 2, not having the silicon-oxide-containing layer 104, had detached portions of the silicon layer 105 from the gate insulating layer 103 as shown by white spots 601 in FIG. 7.

### Example 3

In this example, the gate insulating layer 103 was formed in accordance with Gate Insulating Formation Conditions 3 (Table 7), the silicon-oxide-containing layer 104 was formed in accordance with Oxidation Conditions 3 (Table 8), and the silicon layer 105 was formed in accordance with Silicon Layer Formation Conditions 3 (Table 9). In order that the effect of dilution factor might be evaluated, samples were prepared with various flow rates of hydrogen gas, and test results were compared among the samples. More specifically, the silicon layer 105 was formed with the flow rate of the silicon-based raw material gas set at a fixed value of 10 sccm, while that of hydrogen gas varied in the range of 1200 to 12000 sccm. Separately, for the evaluation of the degree of crystallinity of the silicon layer 105, samples of a silicon monolayer on a glass substrate were prepared. The film formation conditions and dilution factors chosen in preparing these monolayer samples were the same as those for the TFT samples.

TABLE 7
Gate Insulating Layer Formation Conditions 3

| Substrate temperature | 350° C. | |
|---|---|---|
| RF power | 0.05 | W/cm² |
| Pressure | 1.6 | Torr |
| Target thickness | 200 | nm |
| SiH₄ flow rate | 200 | sccm |
| NH₃ flow rate | 1000 | sccm |
| N₂ flow rate | 3000 | sccm |

TABLE 8
Oxidation Conditions 3

| Temperature | 300° C. | |
|---|---|---|
| Pressure | 10 | Torr |
| O₂ flow rate | 100 | sccm |
| Exposure time | 30 | sec |

TABLE 9
Silicon Layer Formation Conditions 3

| Substrate temperature | 220° C. | |
|---|---|---|
| RF power | 0.17 | W/cm² |
| Pressure | 9.0 | Torr |
| Target thickness | 40 | nm |
| SiH₄ flow rate | 10 | sccm |

| | |
|---|---|
| H₂ flow rate | 1200 to 12000 sccm |

The finished samples of a bottom-gate TFT were observed under a TEM. As in Example 2, the silicon-oxide-containing layer 104 was observed as a white line between the gate insulating layer 103 and the silicon layer 105. On the obtained TEM image, the thickness of the silicon-oxide-containing layer 104 was 5 nm, and that of the silicon layer 105 was 42 nm.

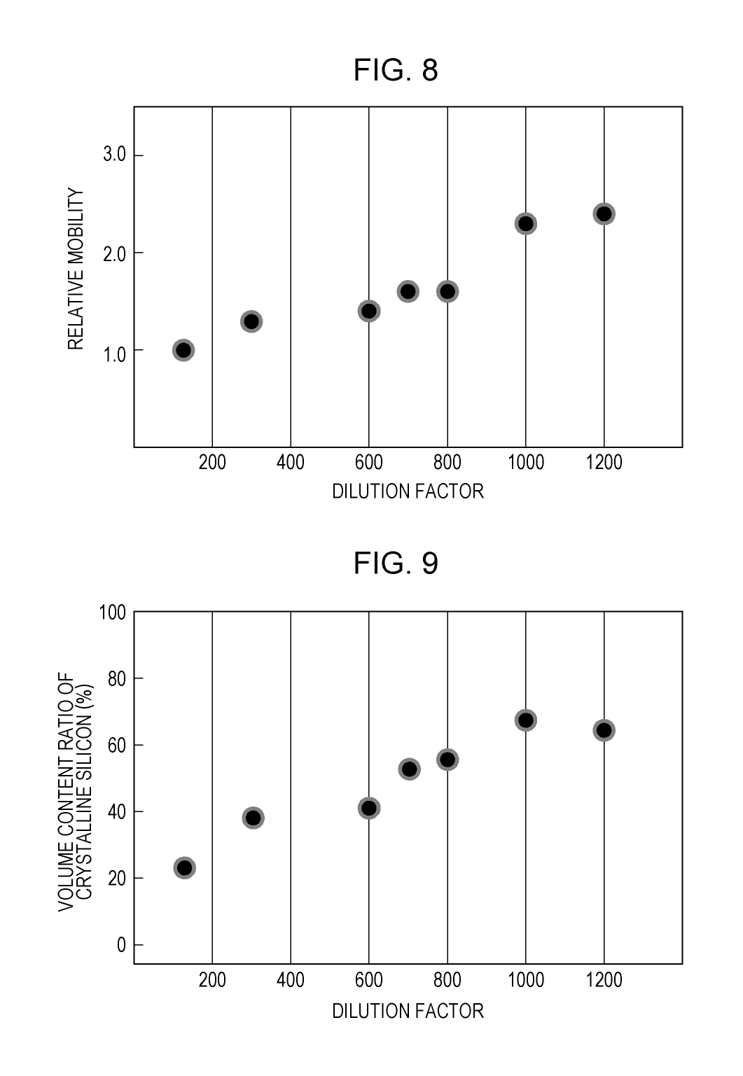

FIG. 8 is a plot of mobility versus dilution factor obtained for samples produced with various dilution factors. When the dilution factor was in the range of 120 to 800, the mobility gradually increased as the dilution factor increased. However, the samples produced with a dilution factor of 1000 or 1200 showed a much greater mobility than the others; the mobility jumped at around a dilution factor of 1000, and the change in mobility was discontinuous. The samples produced with a dilution factor of 1000 or more had a mobility greater than double that of the sample produced with a dilution factor of 120; the former samples were superior in characteristic to the latter one.

Then, the samples of a silicon monolayer were analyzed by Raman spectroscopy to determine the volume content ratio of crystalline silicon in them. The analyzer used was Nicolet Almega XR micro laser Raman system (Thermo Fisher Scientific Inc.), and the wavelength of laser was 532 nm. FIG. 9 illustrates a result. The volume content ratio of crystalline silicon increased as the factor of dilution in hydrogen increased, and reached approximately 70% when the dilution factor was 1000. Unlike the change in mobility, however, the change in the volume content ratio of crystalline silicon was continuous even at around a dilution factor of 1000.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-057728 filed Mar. 15, 2010 and No. 2011-029998 filed Feb. 15, 2011, which are hereby incorporated by reference herein in their entirety.

What is claimed is:

1. A semiconductor device comprising:
a substrate;
a gate electrode;
a gate insulating layer containing silicon nitride;
a silicon layer containing crystalline silicon and amorphous silicon;
a contact layer; and
source and drain electrodes, all layered in this order, and in the silicon layer, the volume content ratio of the crystalline silicon increasing toward the source and drain electrodes and decreasing toward the substrate, wherein
the gate insulating layer and the silicon layer sandwich a silicon-oxide-containing layer therebetween.

2. The semiconductor device according to claim 1, wherein
the volume content ratio of the crystalline silicon averaged over the entire thickness of the silicon layer is equal to or higher than 20%.

3. The semiconductor device according to claim 1, wherein
the silicon-oxide-containing layer has a thickness equal to or smaller than 20 nm.

4. A method for manufacturing a semiconductor device comprising steps of:
(A) forming a gate electrode and a gate insulating layer containing silicon nitride on a substrate in this order;
(B) forming a silicon-oxide-containing layer on the gate insulating layer;
(C) forming a silicon layer containing crystalline silicon and amorphous silicon by chemical vapour deposition on the silicon-oxide-containing layer; and
(D) forming a contact layer and source and drain electrodes on the silicon layer in this order.

5. The method for manufacturing a semiconductor device according to claim 4, wherein
in the step of (B), the silicon-oxide-containing layer is formed by exposing the gate insulating layer to water vapour, oxygen, or an oxygen-containing mixed atmosphere.

6. The method for manufacturing a semiconductor device according to claim 4, wherein
in the step of (B), the silicon-oxide-containing layer is formed by chemical vapour deposition.

7. The method for manufacturing a semiconductor device according to claim 4, wherein
the chemical vapour deposition in the step of (C) is performed by using raw material gas containing silicon atoms and dilution gas containing hydrogen or inert gas, and a flow rate of the dilution gas is 1000 times or more higher than a flow rate of the raw material gas in a chemical vapour deposition chamber.
